(19) United States
(12) Patent Application Publication
(10) Pub. No.: US 2009/0185348 A1
(43) Pub. Date: Jul. 23, 2009

(54) System For Cooling Electrical Components And Devices

(75) Inventors: Rainer Bretschneider, Meissen (DE); Lars Gallasch, Löthain (DE); Wolfgang Trepte, Zehren (DE)

Correspondence Address: HARNESS, DICKEY & PIERCE, P.L.C., P.O. BOX 828, BLOOMFIELD HILLS, MI, 48303, US

(73) Assignee: Knuerr AG, Arnstorf (DE)

(21) Appl. No.: 12/225,126

(22) PCT Filed: Mar. 9, 2007
(86) PCT No.: PCT/EP2007/002096

§ 371 Date: Sep. 15, 2008

(30) Foreign Application Priority Data
Apr. 21, 2006 (DE) 20 2006 006 441.9

(51) Int. Cl. H05K 7/20

(52) U.S. Cl. 361/695

(57) ABSTRACT

The invention relates to a system for cooling electrical and electronic components and devices placed in a housing. The invention is particularly intended for outdoor cabinets and housings of the telecommunications technology.

In order to create a cooling system in which an inexpensive filter is used and positioned in such a way as to ensure an extremely good sealing action, a filter trough is placed in a housing wall or door, in which the filter is received so as to be detachable and replaceable from the outside and is sealed against the filter trough on its air outlet side with the aid of a circumferential seal.

The invention relates to a system for cooling electrical and electronic components and devices placed in a housing in accordance with the preamble of claim 1.

The invention is particularly intended for housings and equipment cabinets of the telecommunications technology and which are set up in the open air as outdoor cabinets and housings. Said outdoor housings and cabinets are to a greater or lesser extent strongly exposed to atmospheric conditions and environmental influences and must be constructed or correspondingly sealed in such a way that foreign bodies, dust, dirt, water and moisture cannot penetrate the interior and lead to a deterioration or failure of the components and devices. Generally it is necessary to respect the protection provisions according to IP classes, e.g. an IP protection value of 55, i.e. the housings and cabinets are protected against dust and must be able to withstand water jets from any direction.

For outdoor housings and cabinets systems are known which have membrane filters in an air inlet of a housing cooperating with at least one fan (DE 197 55 944 C2). The membrane filters are used for the surface filtering of dirt particles from the fresh air sucked in and the separation of moisture and liquids. The membrane filters, which are e.g. made from polytetrafluoroethylene (Teflon) with a stabilizing support material, have a very small pore size and are held in a folded arrangement in a filter frame. Therefore a large filter surface and a very limited flow resistance for the cooling air are achieved.

In the known systems the membrane filters are located on the inside of a housing wall or door, which is provided with ventilation holes. Sealing of the membrane filter takes place on the fresh air side of the filter facing the housing wall or door. The effect of the seal is impaired through the pressure difference between the internal air pressure and the external air pressure. In addition, with said arrangement it is necessary to have a filter material with an absolute fluid tightness. In the case of very heavy precipitation and in spite of a corresponding construction of the ventilation holes, e.g. with a lamellar construction, water can enter the filter, which with the present use leads to the formation of a water level which exceeds the efficiency of the seal designed for water jets and leads to a risk of leaks. Also in the case of a corresponding exposure to dust and dirt, it is not possible to prevent clogging of the membrane filter. It is then necessary to replace the entire filter. As the costs for a membrane filter are relatively high, particularly if the filter is made from a flammable material and it is also necessary to provide a fire protection plate and also the fixing of the filter which generally occurs using a screwed flange which is relatively time consuming, the replacement of a filter involves relatively high costs.

The object of the invention is to provide a cooling system, in which an inexpensive filter is used and positioned in such a way that an extremely good seal is obtained.

According to the invention the object is achieved by the features of claim 1. Appropriate and advantageous developments appear in the subclaims and the description relative to the drawings.

It is a fundamental idea of the invention to position a filter from the outside using a holding means or device, referred to hereinafter as a filter trough, instead of from the inside on a housing wall or door so as to be sealed against the same.

According to the invention the filter trough is placed in a housing wall, particularly in a door of the housing and the filter received in the filter trough is sealed with the aid of a circumferential seal on the air outlet side against the filter trough, preferably in the region of the trough bottom.

The filter trough can be constructed as a relatively shallow holding device and preferably in the form of a depression.

An essential advantage of this arrangement is that as a result of the suction action of the vacuum prevailing in the interior of the housing, the filter is pressed against the seal and thereby aids the sealing action. This increased sealing action ensures a higher security against secondary air and the entry of water. Only filtered and dehumidified or aerosol-free cooling air can enter the interior and reach the modules and devices received therein and the necessary removal of the dissipated heat is achieved. The devices and modules are not impaired by environmental and atmospheric influences and a corresponding service life is ensured.

A further advantage is that the filter to be placed in detachable manner from the outside in the filter trough can be a glass fibre mat or polypropylene filter. These filters are known per se and are e.g. used in the motor vehicle and building or construction industries. They generally comprise a folded fine filter and a coarse filter, so as to implement a water drain. Advantageously the glass fibre mat and polypropylene filters are much less expensive than membrane filters and with respect to the pore size and separation efficiency for dust and aerosols and also with respect to the pressure losses they satisfy the necessary requirements.

Through the placing of the filter in a filter trough the formation of a water level is prevented. In conjunction with the filter design it is possible to reliably ensure an outflow of collecting fluid.

The circumferential seal provided between the filter of filter frame and filter trough, particularly in the vicinity of the trough bottom, can be constructed as a sealing frame or a dispensed seal, clip-on seal or adhesive seal.

Appropriately the filter trough and in particular the filter received therein is covered with the aid of a filter cover, so that the filter is protected against environmental and atmospheric influences. The filter cover is advantageously detachably fixed to the door or housing wall in which the filter trough is formed and in the case of a necessary filter change can be relatively speedily removed, so that the filter in the filter trough is accessible.

The filter trough can be integrated into the housing wall and especially in a door. However, it is also possible to place the filter trough in a recess of the door or a housing wall. Appropriately the filter trough is then provided with an attachment or fixing flange, which externally overlaps the recess and engages on a marginal area of the door or housing wall bounding the recess.

Advantageously the filter cover is spaced from the filter trough and the filter received therein. As a result a suction duct or an air distribution area is formed over the entire air inlet side of the filter. This arrangement makes it possible to so arrange air inlet or suction openings that sprayed or jet water can never act directly on the filter material.

The air inlet openings for the fresh air sucked in by at least one fan from the housing environment are appropriately formed in the bottom of the filter cover and for separating moisture from the fresh air before it reaches the filter advantageously separating elements, e.g. separating plates are located in the lower area of the suction duct.

At the bottom the filter frame can be provided on the fresh air side with drain holes for separated water or fluid, so as to prevent damage to the filter.

Advantageously spacers are provided on the inside of the filter cover and extend up to the filter, so as to assist a stable arrangement of the filter and the sealing thereof in the filter trough.

It is advantageous that the filter trough can simultaneously assume the function of a fire protection plate. The filter trough can e.g. be integrated into the plane of a door leaf or side panel in such a way that, apart from the seals, it only has a two-dimensional extension. The filter cover should then be made correspondingly higher.

The trough bottom, which is positioned parallel to the filter and filter cover and is in particular vertical, has openings for the filtered fresh air.

The fan can advantageously be located in an upper area and in a housing wall, e.g. in the rear wall, which faces the door or housing wall with the filter trough and the filter received therein. If the filter and the complementary constructed filter trough only take up a partial area of the door or a housing wall, the fan can also be placed above the filter and filter trough. An appropriate fan arrangement can also comprise a fan installation above or below the cabinet cover and protected by a lean-to roof or shelter.

In particularly appropriate manner there is a front door with a filter trough for receiving a glass fibre mat or polypropylene filter. The fan is then positioned in the upper area of the rear wall and the outgoing or exhaust air exposed to the dissipated heat can be led off to the environment, appropriately in an exhaust air duct, which can be formed by a double rear wall. Exhaust air openings in the double rear wall are then advantageously formed in a bottom region. The same procedure can apply when a fan is arranged below the lean-to roof or in the door.

The invention is described in greater detail hereinafter relative to the attached diagrammatic drawings, wherein show:

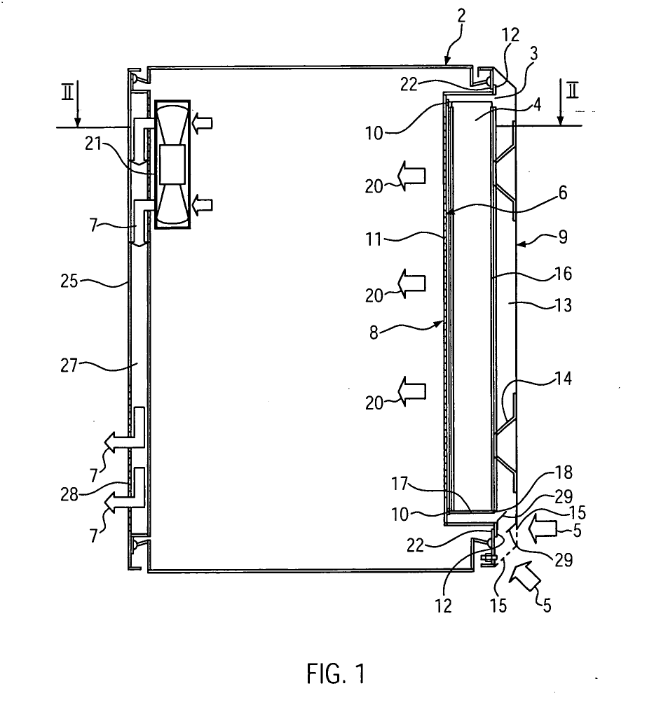

FIG. 1 a longitudinal section through an inventive system;

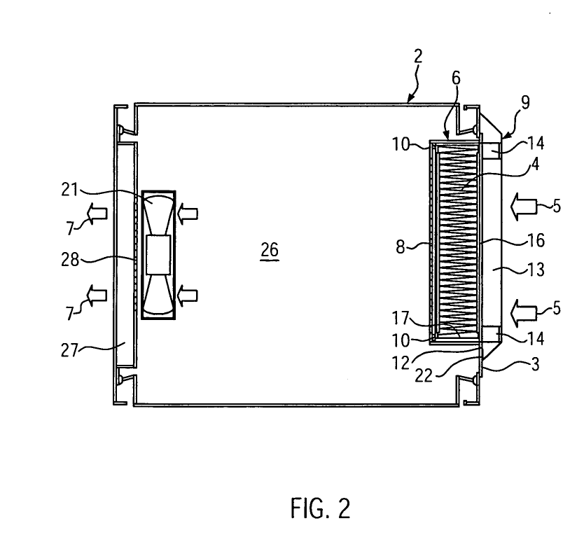

FIG. 2 a horizontal section along line II-II of FIG. 1;

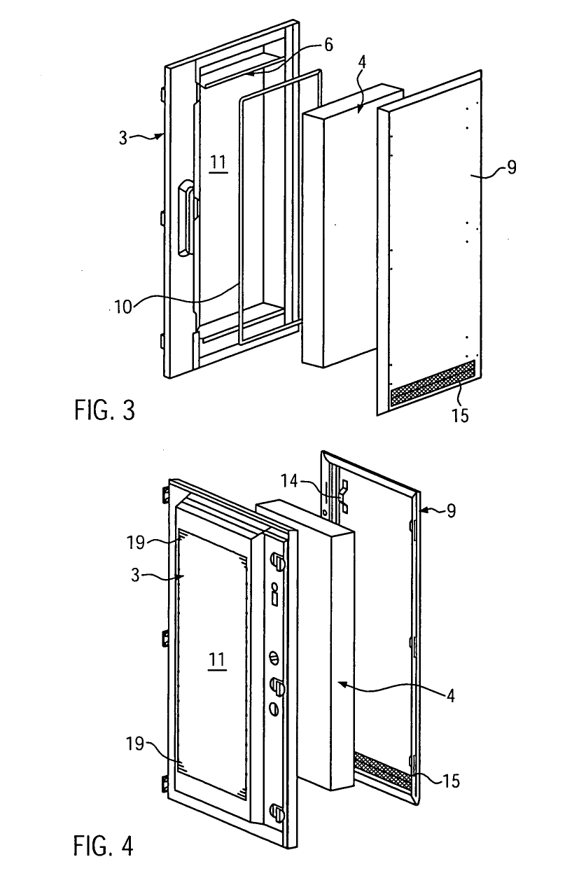

FIG. 3 an exploded view of the filter arrangement seen from the outside;

FIG. 4 an exploded view of the filter arrangement seen from the inside.

In the case of the system for cooling electrical and electronic components, modules and devices (not shown) shown in FIGS. 1 and 2 a fan 21 is located in the upper area of a rear wall 25.

For removing the dissipated heat from the modules and devices in the interior 26 of housing 2, the fan 21 sucks in fresh air 5 via air inlet openings 15 and a filter arrangement in the vicinity of a front door 3. The filter arrangement comprises a filter 4, which can be a glass fibre mat filter or a polypropylene filter and which is placed in a filter frame 17. Filter 4 is received in a filter trough 6, which in this embodiment is constructed as a depression and is located in a recess 23 of the door 3.

In principle, the filter trough 6 is constructed in complimentary manner to the filter 4 and closes off a fresh air side 16 of the filter 4 in virtually flush manner with the filter trough 6, whereas on an air outlet side 8 of the filter 4 a circumferential seal 10 is provided for sealing the filter 4 against the filter trough 6. The seal 10 engages in the vicinity of a trough bottom 11 and therefore on the suction side, which increases and improves the sealing action. The trough bottom 11 is provided with openings 19, through which the filtered fresh air 20 enters the interior 26 of the housing 2.

Filter trough 6 has attachment flanges 12 and the latter overlap a marginal area 22 of the door 3, which surrounds the recess 23 of said door 3.

Externally and spaced from the filter 4 is provided a filter cover 9, in whose bottom region are formed the air inlet openings 15 for the fresh air 5. Apart from producing a sealing pressure, said filter cover 9 protects against direct exposure of the filter 4 to fluid particles from the fresh air and as a result of a detachable arrangement on the door 3 also a rapid replacement of the filter 4 when this proves necessary.

As a result of the spaced arrangement of the filter cover 9 a suction duct 13 is formed, in which the sucked in fresh air 5 is distributed and passes over the entire surface of filter 4 into the interior 26. Spacers 14 are fixed to the inside of the filter cover 9 and extend to the fresh air side of the filter 4. In the bottom region close to the air inlet openings 15 for the fresh air 5 are provided separating plates 29 for fluid droplets in the fresh air 5 and in the bottom filter frame 17 there are drain holes 18 for penetrated fluid.

The rear wall 25 of the housing 2 is in double-wall form in this embodiment and provided on the inside in the vicinity of the fan 21 and on the outside in a lower area with exhaust air openings 28. The exhaust air sucked in by fan 21 is removed to the housing environment via the exhaust air duct 27 and the bottom exhaust air openings 28.

FIG. 2 additionally illustrates the longitudinal folding of the filter 4. Otherwise identical features carry identical reference numerals.

The exploded views of FIGS. 3 and 4 show a filter trough 6, which is integrated into a door 3 and formed as a depression (cf. FIG. 4). For sealing the filter 4 relative to the filter trough 6 a seal 10 is constructed in frame-like manner and is located between the filter 4 and filter trough 6 in the vicinity of the trough bottom 11.

A filter cover 9 is detachably placed from the outside and covers the filter 4 and filter trough 6. Air inlet openings 15 for the fresh air 5 (cf. FIGS. 1 and 2) are formed at the bottom of the filter cover 9.

FIG. 4 additionally shows spacers 14, which are fitted to the inside of the filter cover 4. It is possible to see that the filter cover 9 is articulated by hinges 30 to the door 3, which makes maintenance and replacement of the filter 4 very simple and rapid.

The fan design shown in the drawings merely constitutes an example and it is also possible to use radial, diagonal or roller fans.

1-15. (canceled)

16. A system for cooling electrical and electronic components and devices placed in a housing, comprising:
at least one fan which supplies fresh air from the housing environment through air inlet openings of the housing to a filter and subsequently to the interior of the housing and removes to the housing environment exhaust air heated by the components and devices,
the filter being located on a housing wall or a door, wherein
a filter trough is provided for positioning of the filter and is located in the housing wall or door and
wherein the filter is detachably received in the filter trough and can be replaced from the outside and is sealed with the aid of a circumferential seal against the filter trough on its air outlet side.

17. The system according to claim 16, wherein the filter is a glass fibre mat filter or a polypropylene filter.

18. The system according to claim 16, wherein the circumferential seal is a sealing frame or is constructed as a dispensed seal, a clip-on seal or an adhesive seal.

19. The system according to claim 16, wherein the filter trough and the filter received therein are covered by an externally positioned filter cover.

20. The system according to claim 16, wherein the filter cover is detachably fixed to the housing wall or door.

21. The system according to claim 16, wherein the filter trough is integrated into the housing wall or door.

22. The system according to claim 16, wherein the filter trough is placed in a recess of the housing wall or door and has an attachment flange, which overlaps the recess and engages on a marginal area.

23. The system according to claim 16, wherein the filter trough is constructed as a virtually planar fire protection plate or as a depression and a trough bottom has openings for the filtered fresh air.

24. The system according to claim 16, wherein the filter has a filter frame which, on the fresh air side is provided at the bottom with drain holes for separated water.

25. The system according to claim 16, wherein the filter cover is placed on the housing wall or door spaced from the filter received in filter trough and a suction duct is formed between the fresh air side of the filter and the filter cover.

26. The system according to claim 16, wherein the air inlet openings for the fresh air are formed in a bottom area of the filter cover.

27. The system according to claim 16, wherein separating plates are provided in a suction duct for reducing the entry of water.

28. The system according to claim 16, wherein spacers are located between the filter cover and filter.

29. The system according to claim 16, wherein the fan is positioned in an upper area of a housing wall or door, which faces the filter trough with the filter.

30. The system according to claim 16, wherein an exhaust air duct with bottom exhaust air openings is formed in a housing wall or door by means of which the exhaust air sucked by the fan can be led off to the housing environment.
